(19) United States
(12) Patent Application Publication
(10) Pub. No.: US 2011/0140590 A1
(43) Pub. Date: Jun. 16, 2011

(54) Light emitting device and manufacturing method therefor

(76) Inventor: Takahiko Nakamura, Chiba-shi (JP)

(21) Appl. No.: 12/928,270

(22) Filed: Dec. 7, 2010

(30) Foreign Application Priority Data
Dec. 11, 2009 (JP) 2009-282135

(51) Int. Cl. H01K 1/26; H05K 3/32

(52) U.S. Cl. 313/113; 29/841

(57) ABSTRACT

Provided is a highly-reliable light emitting device which has good heat radiation capacity and uses a light emitting diode (LED) having high luminance and high output as a light source. The light emitting device includes: the light source; a first metal substrate on which the light source is mounted; a wire connected to the light source; a second metal substrate electrically connected to the light source by the wire and formed on the same plane as the first metal substrate to be insulated from the first metal substrate; a planar reflecting member placed on the first metal substrate and the second metal substrate, having a through hole that is smaller in diameter on the light source side than on a side opposite to the light source side, and having a side surface formed of an inclined reflecting surface on the through hole side; an encapsulant for covering the light source; a slit formed between the first metal substrate and the second metal substrate; and an insulating material for filling the slit.

### BACKGROUND OF THE INVENTION

1. Field of the Invention

The present invention relates to a light emitting device which uses a light emitting diode (LED) element having high luminance and high output as a light source, and to a manufacturing method for the light emitting device. More specifically, the present invention relates to a light emitting device which is improved in heat radiation effect to thereby extend lifetime of an LED element.

2. Description of the Related Art

A conventional LED package is constructed by mounting an LED element serving as a light source on a patterned electrode of a circuit board, and integrally fixing a front surface of the board and a reflecting member having a reflecting surface, which passes through the reflecting member at an inclination angle, by epoxy resin or the like. The external size of the reflecting member is substantially the same as that of the board. In the LED package constructed as above, the reflecting surface reflects light from the LED element to the front.

The above-mentioned LED package, however, does not use a material having high heat conductivity and hence an excellent heat radiation function as the board material. Therefore, an excellent heat radiation effect cannot be obtained during the light emission operation of the LED element. Further, the reflecting member is fixed to the board in a separate step, to thereby hinder simplification of the manufacturing process and hence increase assembly cost.

In order to overcome the above-mentioned disadvantages, for example, Japanese Patent Application Laid-open No. 2007-294966 (hereinafter, referred to as Patent Document 1) proposes a fabrication method for an LED package. The structure of Patent Document 1 is briefly described with reference to FIG. 7. As illustrated in FIG. 7, an LED package 70 includes: an aluminum substrate 71 having a surface in which a multi-stepped recess is formed; a light source 74 which is mounted on a bottom surface of the recess and electrically connected to a patterned electrode 73 by a wire 75; an anodized insulation layer 72 formed between the patterned electrode 73 and the aluminum substrate 71; and an encapsulant 76 covering the light source on the substrate. Further, an aluminum radiator is formed under the LED element serving as the light source, to thereby provide an LED package having excellent heat radiation capacity and a fabrication method therefor. According to the invention of Patent Document 1, the substrate is made of an aluminum material and anodized to form the insulation layer. Therefore, an excellent heat radiation effect may be obtained, to thereby increase useful lifetime and light emission efficiency of the LED package.

However, in the above-mentioned LED package, even though the used aluminum has a heat conductivity of 236 W/m·K, the anodized insulation layer 72 has a heat conductivity of 32 W/m·K, to thereby reduce the heat conductivity. In addition, with the insulation layer 72 having porous structure and the encapsulant 76 covering the insulation layer 72, air bubbles are apt to be generated from the insulation layer part at the time when the encapsulant is formed, which leads to a problem of causing defects of incorporated air bubbles. Further, sulfide or other similar gas reaches inside the package through the insulation layer. Therefore, when a material containing silver is used to fix the reflecting film and the LED element, there is another problem of accelerated degradation.

### SUMMARY OF THE INVENTION

In order to solve the above-mentioned problems, a light emitting device according to the present invention is constructed as follows. Specifically, the light emitting device includes: a light source; a first metal substrate on which the light source is mounted; a second metal substrate formed on the same plane as the first metal substrate to be insulated from the first metal substrate; a wire electrically connected between the light source and the second metal substrate; a planar reflecting member placed on the first metal substrate and the second metal substrate, having a through hole that is smaller in size on the light source side than on a side opposite to the light source side, and having a side surface formed of an inclined reflecting surface on the through hole side; an encapsulant for covering the light source; a slit formed between the first metal substrate and the second metal substrate; and an insulating material for filling the slit.

Further, each of the first metal substrate and the second metal substrate is made of a material selected from the group consisting of copper, silver, gold, and aluminum. Further, the inclined surface of the reflecting member is formed of at least one of a cold mirror film, a silver film, and an aluminum film. In this case, the encapsulant is suitably made of a hydrophobic material. Further, the encapsulant and the insulating material may be made of the same material.

Further, a manufacturing method for a light emitting device according to the present invention includes: forming a slit in a third metal substrate to divide the third metal substrate into a first metal substrate, which is a part on which a light source is mounted, and a second metal substrate, which is a part to be connected by a wire bond; placing a reflecting member, in which an inclined through hole is formed, on the third metal substrate; mounting the light source on the third metal substrate; electrically connecting the third metal substrate and the light source by the wire; and supplying an encapsulant and an insulating material. Alternatively, instead of supplying the encapsulant and the insulating material for the slit at the same time, the insulating material may be formed first in the slit, then the reflecting member may be placed on the third metal substrate, and finally the encapsulant may be supplied.

Another example of the method of joining the third metal substrate and the light source may be by sintering metal nanoparticles.

The manufacturing method further includes segmenting the third metal substrate into a plurality of the light emitting devices collectively formed on the third metal substrate. In this case, the segmenting may be facilitated by using a reflecting member having a groove in bonding or joining the reflecting member and the third metal substrate.

According to the present invention, a heat radiating path without a part in which the heat conductivity is reduced may be secured, and hence it is possible to realize the light emitting device having high heat radiation capacity. Further, the reflecting member does not have porous structure, and hence it is possible to realize the highly-reliable light emitting device without a defect in sealing by the encapsulant.

### BRIEF DESCRIPTION OF THE DRAWINGS

In the accompanying drawings:

FIG. 1 is a cross-sectional view illustrating a light emitting device according to the present invention;

FIGS. 2A to 2F illustrate manufacturing steps of the light emitting device according to the present invention;

FIG. 3 is a top view in a manufacturing step of the light emitting device according to the present invention;

FIGS. 4A to 4D illustrate manufacturing steps of the light emitting device according to the present invention;

FIGS. 5A to 5F illustrate manufacturing steps of the light emitting device according to the present invention;

FIGS. 6A to 6F illustrate manufacturing steps of the light emitting device according to the present invention; and

FIG. 7 is a cross-sectional view of a prior art example.

### DETAILED DESCRIPTION OF THE PREFERRED EMBODIMENT

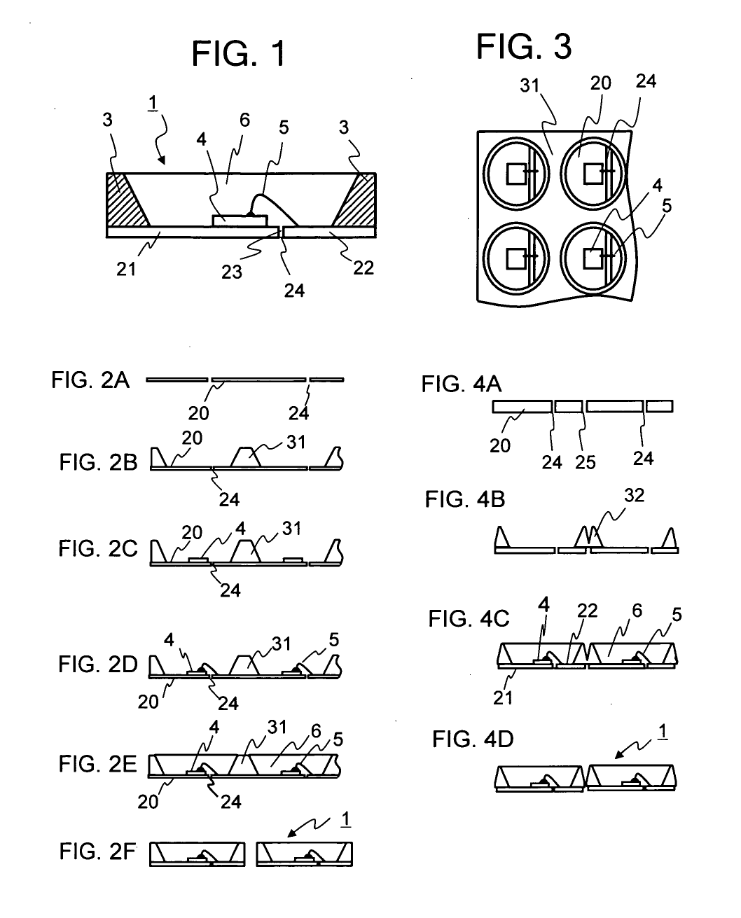

An embodiment of the present invention is described with reference to the attached drawings. FIG. 1 is a cross-sectional view illustrating a light emitting device 1 according to the present invention. The light emitting device 1 is constructed on the basis of a first metal substrate 21 and a second metal substrate 22 arranged across a slit 24. A light source 4 is mounted on the first metal substrate 21. The second metal substrate 22 is electrically connected to the light source 4 by a wire 5. The first metal substrate 21 and the second metal substrate 22 are insulated from each other by the slit 24. Further, a reflecting member 3 is placed on the first metal substrate 21 and the second metal substrate 22. An encapsulant 6 covers the light source 4. The slit 24 is filled with an insulating material 23 to maintain insulation between the first metal substrate 21 and the second metal substrate 22. A through hole is formed in the reflecting member 3. The through hole is inclined, and hence its side surface is an inclined surface. The light source 4 is mounted in the through hole. The through hole is smaller in diameter on the light source side than on a side opposite to the light source side. The inclined surface reflects light from the light source 4. The first metal substrate 21 and the second metal substrate 22 are joined together through the reflecting member 3. Note that, the slit 24 may be filled with the encapsulant 6 instead of the insulating material 23.

Examples of the material of the first metal substrate 21 and the second metal substrate 22 include aluminum having a heat conductivity of 236 W/m·K, gold having a heat conductivity of 320 W/m·K, silver having a heat conductivity of 420 W/m·K, and copper having a heat conductivity of 398 W/m·K. The thickness of the first metal substrate 21 and the second metal substrate 22 is suitably 10 μm to 100 μm in view of heat radiation capacity, structural strength, manufacturability, and the like. When the first metal substrate 21 and the second metal substrate 22 are made of copper, rust prevention processing such as gold plating or tin (Sn) plating may be applied to suppress corrosion.

The reflecting member 3 may be made of, for example, glass or ceramic. Further, for example, a silver film, an aluminum film, or a cold mirror film may be formed on the inclined surface of the reflecting member 3 to increase the reflection efficiency.

The reflecting member 3 may be placed on the first metal substrate 21 and the second metal substrate 22 by bonding with epoxy resin, acrylic resin, double coated tape, an adhesive, or the like.

Alternatively, when the reflecting member 3 is made of glass, a silicon thin film or aluminum thin film having a thickness of, for example, 1,000 Å to 5,000 Å may be formed on the surface of the first metal substrate 21 and the second metal substrate 22 to be joined by anodic bonding. When, however, the first metal substrate 21 and the second metal substrate 22 are formed of aluminum, anodic bonding may be performed without forming the above-mentioned thin film.

Alternatively, when the reflecting member 3 is made of ceramic, brazing may be performed by using, for example, silver braze.

By adopting the above-mentioned methods, it is possible to produce a device that is more reliable than the one obtained by bonding with an adhesive.

It is preferred that the encapsulant 6 be transparent and hydrophobic. For example, a transparent resin is suitably used, and examples of the transparent resin include epoxy resin, acrylic resin, silicon resin, polysiloxane resin, and the like. Further, a fluorescent substance or the like may be mixed in the transparent resin. The insulating material 23 may also use a similar material.

The light source 4 and the first metal substrate 21 are joined together by using a conductive adhesive called a die bonding material, such as silver paste. Alternatively, the light source 4 and the first metal substrate 21 are joined together by sintering metal nanoparticles of, for example, silver, gold-tin alloy, gold, copper, or the like in view of heat radiation capacity, to thereby attain a joint that is free of resin components and high in heat conductivity.

Next, a manufacturing method for the light emitting device is described. The manufacturing method according to the present invention includes: producing a reflecting member having an inclined through hole; forming a slit in a third metal substrate to insulate a first metal substrate and a second metal substrate from each other; joining the reflecting member to the third metal substrate; mounting a light source on a region of the third metal substrate that corresponds to the first metal substrate; electrically connecting the light source and a region of the third metal substrate that corresponds to the second metal substrate by a wire; supplying an encapsulant so as to cover the light source and the wire; dividing the third metal substrate into the first metal substrate, which is a part on which the light source is mounted, and the second metal substrate, which is a part electrically connected to the light source by the wire; and filling the slit with an insulating material. In this method, the reflecting member may be joined to the third metal substrate before mounting the light source, or the reflecting member may be joined to the third metal substrate after mounting the light source. Further, supplying the encapsulant and filling the slit with the insulating material may be performed at the same time.

Next, referring to FIGS. 2A to 6F, manufacturing steps of the light emitting device according to the present invention are described in detail. FIGS. 2A to 2F are diagrams illustrating manufacturing steps of the light emitting device, which constitute a method involving manufacturing a plurality of light emitting parts for each wafer and segmenting the wafer into the individual light emitting parts in the final step. FIG. 2A illustrates a third metal substrate 20 in which the slit 24 is formed for forming the first metal substrate 21 and the second metal substrate 22. The third metal substrate 20 includes a thin film (not shown) formed thereon depending on the material of a reflecting member in which a plurality of inclined through holes are integrally formed, and a placement method such as joining or bonding to the reflecting member. Further, a mounting pattern for the light source 4 and the wire 5 may be formed by a gold film or the like.

FIG. 2B illustrates a step of placing the reflecting member, in which the plurality of inclined through holes are integrally formed, on the third metal substrate 20 by bonding, joining, or the like. The inclined through holes are formed by blasting, etching, drilling, powder burning, or the like, depending on the material of the reflecting member.

FIG. 2C illustrates a step of mounting the light source 4 on the third metal substrate 20. In this case, the light source is mounted on a part of the third metal substrate 20 that is to form the first metal substrate. In this step, the third metal substrate 20 and the light source 4 are joined together by sintering metal nanoparticles of silver, gold-tin alloy, gold, copper, or the like. Through this step, a joining layer made of the above-mentioned metal is formed between the third metal substrate 20 and the light source 4. Alternatively, the third metal substrate 20 and the light source 4 may be joined together by using a conductive adhesive called a die bonding material, such as silver paste.

FIG. 2D illustrates a step of electrically connecting the light source 4 and a part of the third metal substrate that constitutes the second metal substrate by the wire 5. FIG. 3 illustrates a top view at this time.

FIG. 2E illustrates a step of forming the encapsulant 6 that covers the light source 4 and the wire 5. In this case, it is preferred that the encapsulant 6 be transparent and hydrophobic. Further, a mixture of a fluorescent substance or the like may be mixed in the encapsulant 6. Further, a film or the like may be attached to the slit 24 from the back side of the third metal substrate, and the film may be removed after the encapsulant 6 is supplied. This way, the encapsulant 6 not only covers the light source 4 but also fills the slit 24. With this configuration, it is possible to provide a highly reliable light emitting part having strong structure. The film used in this case may be used not only at the time of FIG. 2E but also at convenient time from FIGS. 2A to 2D for sealing.

FIG. 2F illustrates a dividing step of segmenting the third metal substrate 20, on which a plurality of light emitting devices have been formed at the same time, by dicing or the like to manufacture the individual light emitting devices. Through this step, the third metal substrate 20 is completely divided into the first metal substrate and the second metal substrate.

Through the above-mentioned steps, the plurality of light emitting devices may be formed collectively on the third metal substrate 20, and then the third metal substrate 20 may be segmented into the individual light emitting devices, to thereby provide an effect of decreasing production cost.

Note that, this embodiment is not limited to the case where the plurality of light emitting parts are formed at the same time, and may also be applied to a case where a single light emitting part is formed. In such case, the first metal substrate and the second metal substrate may be made of different materials.

Next, referring to FIGS. 4A to 4D, a method of manufacturing the light emitting device more easily is described. Redundant descriptions of the same portions as the above descriptions are omitted as appropriate. As illustrated in FIG. 4A, a slit 25 for separation is also formed in the third metal substrate 20 at the place for segmenting the third metal substrate 20 into the individual light emitting devices 1. Then, as illustrated in FIG. 4B, a reflecting member 32 having a groove at the place for segmenting the third metal substrate 20 into the individual light emitting devices 1 is placed on the third metal substrate 20 to join the third metal substrate 20 with another third metal substrate 20. Thereafter, steps of FIGS. 20 to 2E are performed as described above. After those steps, the form illustrated in FIG. 4C is obtained. With this method, in the step of dividing the light emitting devices illustrated in FIG. 4D, only the reflecting member 32 needs to be cut, and there is no need to cut different materials. Therefore, the precision may be improved, the cost may be reduced, and cutting method options are increased. Further, in the structure in which the groove is formed in the reflecting member 32 to concentrate the stress, cutting may be performed in the same way as breaking, to thereby separate the light emitting devices rapidly with no need for a special apparatus.

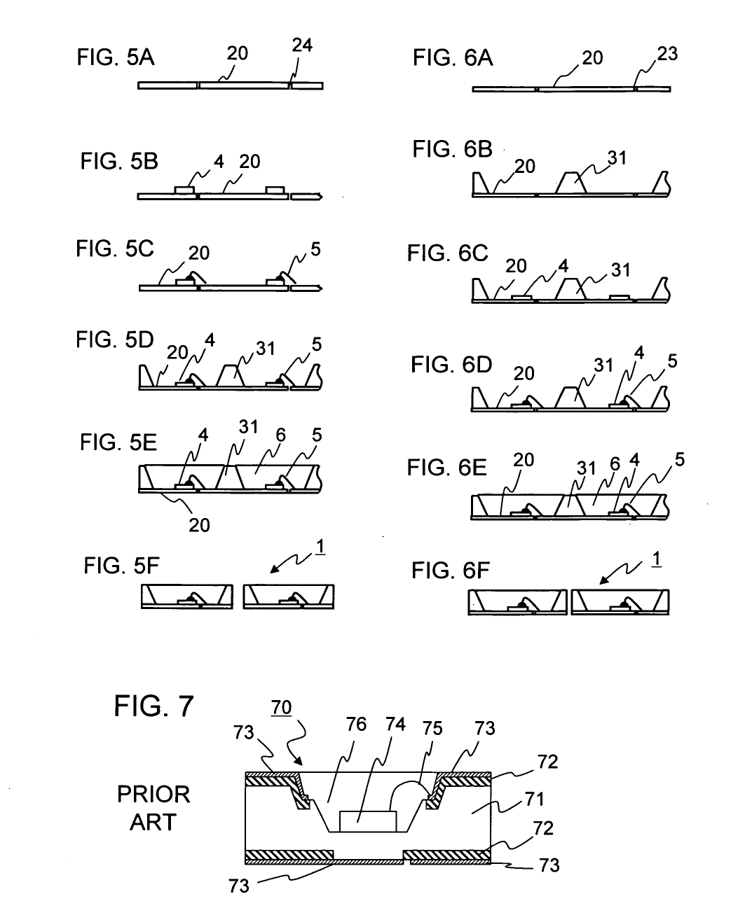

Next, referring to FIGS. 5A to 5F, a method of manufacturing the light emitting device more easily is described. The method illustrated in FIGS. 5A to 5F is different from FIGS. 2A to 2F in that the step of mounting the light source 4 (FIG. 5B) and the step of electrically connecting the light source 4 and the part of the third metal substrate that is to form the second metal substrate by the wire 5 (FIG. 5C) are first performed, and then the step of bonding or joining the reflecting member 31, in which the plurality of inclined through holes are integrally formed, to the third metal substrate 20 (FIG. 5D) is performed. With this method, the light sources are not mounted in holes but on a plane. Therefore, the method allows a commonly-used tool to be used for manufacturing at high speed and low cost.

Referring to FIGS. 6A to 6F, another manufacturing method for the light emitting device is described. The method described here involves using the third metal substrate 20 having the slit 24 previously filled with the insulating material 23. As illustrated in FIG. 6A, the slit of the third metal substrate 20 is filled with the insulating material 23. The following steps illustrated in FIGS. 6B to 6F are performed similarly to the steps of FIGS. 2B to 2F. Alternatively, a material having a light reflecting property may be used as the insulating material 23. Using such material eliminates the need for a sealing film, to thereby allow the light emitting part to be produced at lower cost and light to be extracted efficiently.

According to the present invention, a light emitting diode (LED) element serving as the light source is joined to one of the divided metal substrates, to thereby provide an excellent heat radiation effect. Therefore, the lifetime and the light emission efficiency of the light emitting device are increased. Further, according to the present invention, a number of the metal substrates and the reflecting members are formed collectively at the same time to be segmented in the final step, to thereby decrease the production cost.

The light emitting device according to the present invention may be used, for example, as a light emitter in a lighting apparatus, an electric bulletin board, or a vehicle headlamp. Alternatively, the light emitting device according to the present invention may be used as a light source in an inspection apparatus for allowing a test object such as a sample to transmit or reflect light to observe and test the object. Examples of the inspection apparatus for which the light emitting device according to the present invention may be used include a counterfeit money detector, an image processing apparatus for finding minute flaws and defects on a metal surface, a detector for minute chemicals such as tissues and DNAs in medical and biological fields, and a resin curing apparatus.

What is claimed is:

1. A light emitting device comprising:
a light source;
a first metal substrate on which the light source is mounted;
a second metal substrate arranged on the same plane as the first metal substrate;
a wire electrically connected between the light source and the second metal substrate;
a reflecting member joined to the first metal substrate and the second metal substrate, having a through hole that is smaller in size on the light source side than on a side opposite to the light source side, and having a side surface formed of an inclined reflecting surface on the through hole side;
an encapsulant for covering the light source;
a slit formed between the first metal substrate and the second metal substrate to insulate the first metal substrate and the second metal substrate from each other; and
an insulating material for filling the slit.

2. A light emitting device according to claim 1, wherein each of the first metal substrate and the second metal substrate is made of a material selected from the group consisting of copper, silver, gold, and aluminum.

3. A light emitting device according to claim 2, wherein:
the reflecting member is formed of glass;
the reflecting member has a surface to be joined to the first metal substrate and the second metal substrate, on which one of an aluminum thin film and a silicon thin film is formed; and
the reflecting member and the each of the first metal substrate and the second metal substrate are joined together by anodic bonding.

4. A light emitting device according to claim 2, wherein:
the reflecting member is formed of ceramic; and
the reflecting member and the each of the first metal substrate and the second metal substrate are brazed together.

5. A light emitting device according to claim 1, wherein the first metal substrate and the light source are joined together by sintering metal nanoparticles.

6. A light emitting device according to claim 5, wherein the metal nanoparticles are nanoparticles of a metal selected from the group consisting of silver, gold-tin alloy, gold, and copper.

7. A light emitting device according to claim 1, wherein the encapsulant and the insulating material are made of the same material.

8. A manufacturing method for a light emitting device comprising:
producing a reflecting member having an inclined through hole;
forming a slit in a third metal substrate to insulate a first metal substrate and a second metal substrate from each other;
joining the reflecting member to the third metal substrate;
mounting a light source on a region of the third metal substrate that corresponds to the first metal substrate;
electrically connecting the light source and a region of the third metal substrate that corresponds to the second metal substrate by a wire;
supplying an encapsulant so as to cover the light source and the wire;
dividing the third metal substrate into the first metal substrate, which is a part on which the light source is mounted, and the second metal substrate, which is a part electrically connected to the light source by the wire; and
filling the slit with an insulating material.

9. A manufacturing method for a light emitting device according to claim 8, wherein the supplying an encapsulant and the filling the slit with an insulating material are performed at the same time.

10. A manufacturing method for a light emitting device according to claim 8, wherein a plurality of the light emitting devices are formed collectively on the third metal substrate, and then the third metal substrate are segmented into the individual light emitting devices.
